(19) United States
(12) Patent Application Publication
(10) Pub. No.: US 2025/0293078 A1
(43) Pub. Date: Sep. 18, 2025

(54) TRANSFER APPARATUS FOR DISPLAY MODULE AND METHOD OF TRANSFERRING DISPLAY MODULE

(71) Applicant: Samsung Display Co., Ltd., Yongin-si (KR)

(72) Inventors: CHUNGHAN SHIM, Yongin-si (KR); YOUNGOK PARK, Yongin-si (KR); SANGYOUNG LIM, Yongin-si (KR); SANGJUN CHEON, Yongin-si (KR)

(21) Appl. No.: 19/072,044

(22) Filed: Mar. 6, 2025

(30) Foreign Application Priority Data
Mar. 15, 2024 (KR) 10-2024-0036384

(51) Int. Cl. H01L 21/683; G01R 31/00; G01R 31/28; G06F 3/041; G06F 3/044; H01L 21/68

(52) U.S. Cl. CPC H01L 21/6838; G01R 31/002; G01R 31/2825; H01L 21/68; G06F 3/0412; G06F 3/044; G06F 2203/04103

(57) ABSTRACT

A transfer apparatus is disclosed that includes a moving stage configured to mount a display module, an ionizer positioned at a side of the moving stage and configured to be spaced apart by a first space of at least about 5 cm from a side edge of the display module, and a fixed moving unit disposed over the moving stage and configured to adsorb and to move the display module, thereby being capable of reducing electrostatic discharge (ESD) failure during transfer of the display module.

### CROSS-REFERENCE TO RELATED APPLICATIONS

This U.S. non-provisional patent application claims priority under 35 U.S.C. § 119 of Korean Patent Application No. 10-2024-0036384, filed on Mar. 15, 2024, the entire contents of which are hereby incorporated by reference.

### BACKGROUND

The present disclosure relates to a transfer apparatus for a display module and a method of transferring a display module.

Multimedia apparatuses such as televisions, laptop computers, navigators, game machines and the like may display images to users through display screens and provide a touch-based input manner which enables users to intuitively and conveniently input information or commands. An electronic apparatus may include a display panel for generating an image and an input sensor for sensing a user touch.

Electrodes of an input sensor or the like may be damaged by static electricity generated in processes of manufacturing electronic apparatuses and, thus, it is desirable to develop an apparatus and method for minimizing the static electricity generated or transferred in the processes.

### SUMMARY

The present disclosure provides a transfer apparatus, which may minimize electrostatic discharge (ESD) failure.

The present disclosure also provides a method of transferring a display module that may reduce or minimize electrostatic discharge during a transfer of a display module.

An embodiment of a transfer apparatus includes: a moving stage configured to mount a display module; an ionizer positioned at a side of the moving stage and configured to be spaced apart by a first space of about 5 cm or more from a side edge of the display module; and a fixed moving unit disposed over the moving stage and configured to adsorb and to move the display module.

In an embodiment, the fixed moving unit may include: a vacuum suction unit having suction holes; and a pickup pad surrounding at least a portion of the vacuum suction unit and configured to contact the display module.

In an embodiment, the vacuum suction unit may be provided with a metal material, and the vacuum suction unit may be configured to be spaced apart from the display module by a second space of about 3 mm or more.

In an embodiment, a surface resistivity of the pickup pad may be about 10¹² Ω/sq or more.

In an embodiment, the first space may be at least about 10 cm.

In an embodiment, the display module may include an active area and a pad area disposed in at least one side of the active area and having a plurality of pads disposed therein, and the first space may be between an edge of the pad area and the ionizer.

In an embodiment, the moving stage may be configured to mount the display module with at least a portion of the pad area protruding from one side of the moving stage.

In an embodiment, the display module may include a display panel and an input sensor disposed on the display panel and including a sensor conductive layer, and the fixed moving unit may be configured to adsorb to an input sensor side of the display panel.

In an embodiment, the moving stage may be configured to mount a plurality of display modules, and the plurality of display modules may be arranged to be parallel to one side of the ionizer.

An embodiment of a transfer apparatus includes: a moving stage configured to mount a display module; an ionizer spaced apart from a side of the moving stage; and a fixed moving unit disposed over the moving stage and configured to adsorb and to move the display module, wherein the fixed moving unit includes a vacuum suction unit having a suction hole, and a pickup pad surrounding at least a portion of the vacuum suction unit and contacting the display module, and wherein the ionizer may be configured to be spaced apart from a side edge of the display module by a first space of about 5 cm or more, and the vacuum suction unit may be configured to be spaced apart from a top surface of the display module by a second space of about 3 mm or more.

In an embodiment, the vacuum suction unit may be provided with a metal material and the pickup pad may be provided with a polymer material.

In an embodiment, a surface resistivity of the pickup pad may be about 10¹² Ω/sq or more.

In an embodiment, the display module may include an active area and a pad area disposed in at least one side of the active area and having a plurality of pads disposed therein, and the first space may be between an edge of the pad area and the ionizer.

In an embodiment, the display module may include a display panel and an input sensor disposed on the display panel and including a sensor conductive layer, and the fixed moving unit may be configured to adsorb an input sensor side of the display module.

An embodiment of a method of transferring a display module includes: providing a display module on a moving stage; arranging the display module and an ionizer to be spaced apart by a space of about 5 cm or more; ion-treating the display module using the ionizer to form an ion-treated display module; and using the fixed moving unit to move the ion-treated display module from the moving stage.

In an embodiment, the fixed moving unit may include a vacuum suction unit having a suction hole defined therethrough, and a pickup pad surrounding at least a portion of the vacuum suction unit, and wherein the moving the display module from the moving stage may include: bringing the fixed moving unit close to the display module so that the pickup pad contacts a top surface of the display module; fixing the display module to the fixed moving unit; and moving the fixed moving unit to transfer the display module to a transfer tray from the moving stage.

In an embodiment, the method may further include: inspecting the display module between the ion-treating the display module and the using the fixed moving unit to move the display module from the moving stage.

In an embodiment, the fixed moving unit may include a vacuum suction unit having a suction hole, and a pickup pad surrounding at least a portion of the vacuum suction unit and contacting the display module, and the vacuum suction unit and the display module may be spaced apart by a second space of about 3 mm or more.

In an embodiment, the method may further include inspecting the display module between the ion-treating the display module and the using the fixed moving unit to move the display module from the moving stage.

In an embodiment, a surface resistivity of the pickup pad may be about 10¹² Ω/sq or more.

In an embodiment, the display module may include a display panel and an input sensor disposed on the display panel and including a sensor conductive layer, and the fixed moving unit may be adsorbed to an input sensor side of the display panel.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram of a display device manufacturing apparatus according to an embodiment of the inventive concept;

FIG. 2 is a perspective view of a display module according to an embodiment;

FIG. 3A is a cross-sectional view of a display module according to an embodiment;

FIG. 3B is a cross-sectional view of a display module according to an embodiment;

FIG. 4 is a perspective view of a transfer apparatus according to an embodiment;

FIG. 5 is a perspective view of a moving stage according to an embodiment;

FIG. 6 is a perspective view of an ionizer according to an embodiment of the inventive concept.

FIG. 7 illustrates a step of a transfer method using a transfer apparatus according to an embodiment;

FIG. 8 is a perspective view of a fixed moving unit according to an embodiment;

FIG. 9 is a perspective view of a portion of a fixed moving unit according to an embodiment;

FIGS. 10A, 10B, and 10C are each a cross-sectional view of a fixed moving unit according to embodiments;

FIG. 11 shows an example operating state of a fixed moving unit according to an embodiment;

FIG. 12 shows a bottom surface of a fixed moving unit according to an embodiment;

FIG. 13 illustrates steps of a method of transferring a display module using a transfer apparatus according to an embodiment;

FIG. 14 is a flowchart of steps of a method of transferring a display module according to an embodiment; and

FIG. 15 is a flowchart of steps of a method of transferring a display module according to an embodiment.

### DETAILED DESCRIPTION

The present disclosure may be variously modified and realized in various forms, and thus specific embodiments will be exemplified in the drawings and described in detail hereinafter. However, it will be understood that the present disclosure is not intended to be limited to the specific forms set forth herein, and all changes, equivalents, and substitutions included in the technical scope and spirit of the claims are included.

It will be understood that when an element or layer is referred to as being “on”, “connected to” or “coupled to” another element or layer, it can be directly on, connected or coupled to the other element or intervening third elements may be present.

Like reference numerals in the drawings refer to like elements. In addition, in the drawings, the thickness and the ratio and the dimension of the element are exaggerated for effective description of the technical contents. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

Terms such as first, second, and the like may be used to describe various elements, but these elements should not be limited by the terms. Such terms are only used for distinguishing one element from other elements. For instance, a first component may be referred to as a second component, or similarly, a second component may be referred to as a first component, without departing from the scope of the present disclosure. The singular expressions include plural expressions unless the context clearly dictates otherwise.

In addition, terms such as “below,” “lower,” “above,” “upper,” and the like are used to describe the relationship of the configurations shown in the drawings. The terms are used as a relative concept and are described with reference to the direction indicated in the drawings.

It should be understood that the terms “comprise”, “include”, and “have” (as well as variations such as “comprising”) are intended to specify the presence of stated features, integers, steps, operations, elements, components, or combinations thereof in the disclosure, but do not preclude the presence or addition of one or more other features, integers, steps, operations, elements, components, or combinations thereof.

It should be understood that “being directly disposed” may mean that there is not an additional layer, film, region, plate or the like between a part of a layer, film, region, plate or the like and another part. For example, “being directly disposed” may mean that disposition of two layers or two members is performed without using an additional member such as an adhesive member therebetween.

Unless otherwise defined, all terms (including technical and scientific terms) used herein have the same meaning as commonly understood by one of ordinary skill in the art to which example embodiments belong. In addition, it will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, a transfer apparatus and a method of transferring a display module using the same according to an embodiment will be described.

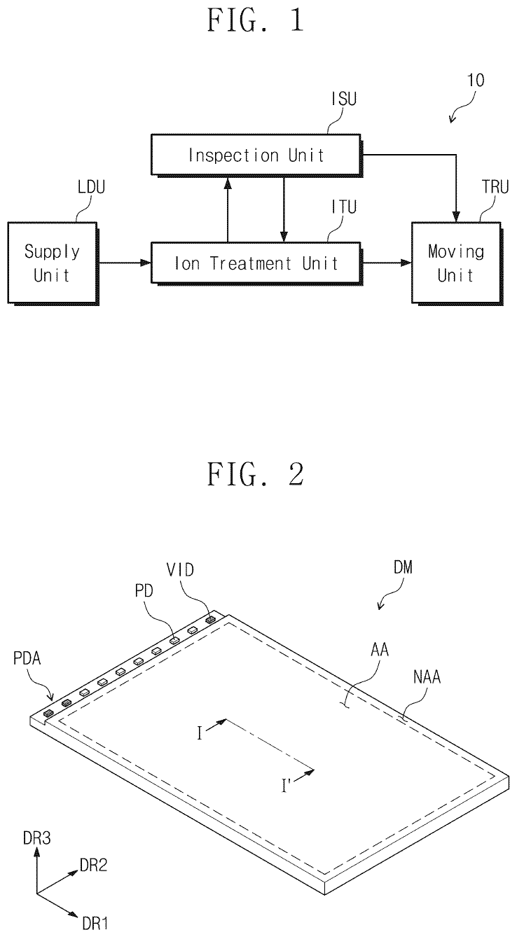

FIG. 1 is a block diagram of a display device manufacturing apparatus according to an embodiment of the inventive concept. The display device manufacturing apparatus 10 may include a supply unit LDU, an ion treatment unit ITU, and a moving unit TRU. In addition, the display device manufacturing apparatus 10 according to an embodiment may further include an inspection unit ISU. The display device manufacturing apparatus of FIG. 1 briefly shows a portion of the manufacturing apparatus in which steps for ion treatment, inspection and the like are performed after a display module DM (see FIG. 2) is manufactured, and then a portion of a step for moving the display module to a moving unit.

The supply unit LDU in the display device manufacturing apparatus 10 according to an embodiment may be a portion for preserving and moving the display module DM (see FIG. 2) manufactured in the previous steps and then transferring the display module to the ion treatment unit ITU. The supply unit LDU may be referred to as an unloader.

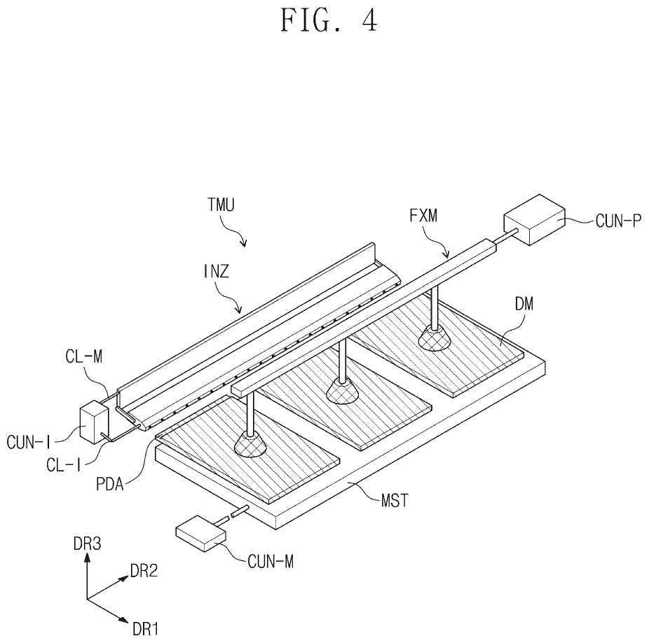

The display module DM (see FIG. 2) loaded on the supply unit LDU may be transferred to the ion treatment unit ITU using a transfer apparatus TMU (see FIG. 4) of an embodiment to be described below. The ion treatment unit ITU may perform an ion treatment process using the ionizer in order to decrease electrostatic discharge. The transfer apparatus TMU (see FIG. 4) of an embodiment may be disposed inside the ion treatment unit ITU. The ion treatment unit ITU may have a chamber shape and be distinguished from other units of the display device manufacturing apparatus. However, the embodiment is not limited thereto, and the ion treatment unit ITU may be disposed in an open space in order for the display module to be easily moved between the neighboring supply unit LDU, moving unit TRU, and inspection unit ISU.

In an embodiment, a portion disposed with the transfer apparatus TMU (see FIG. 4) may be referred to as the ion treatment unit ITU. In order to move the display module to the neighboring supply unit LDU, moving unit TRU, and inspection unit ISU, a portion of components of the transfer apparatus TMU (see FIG. 4) may be moved to the supply unit LDU, the moving unit TRU, the inspection unit ISU or the like besides the ion treatment unit ITU.

The moving unit TRU in the display device manufacturing apparatus 10 of an embodiment may be a unit in which the display module ion-treated in the ion treatment unit ITU is moved. The ion-treated display module is moved to other facilities of the display device manufacturing apparatus using the moving unit TRU and then manufactured into a display device through successive processes.

The inspection unit ISU in the display device manufacturing apparatus 10 of an embodiment may be a unit for inspecting the quality of the display module. The inspection unit ISU may inspect the operation, the appearance quality, or the like of the display module of which the static electricity is eliminated by ion treatment in the ion treatment unit ITU after being supplied by the supply unit LDU. For example, the inspection unit ISU may inspect the operation performance of the input sensor of the display module.

The display module inspected by the inspection unit ISU may be moved to the moving unit TRU. The display module may be directly transferred to the moving unit TRU from the inspection unit ISU, or transferred to the moving unit TRU via the ion treatment unit ITU from the inspection unit ISU.

A step of a display device manufacturing method using the display device manufacturing apparatus 10 according to an embodiment may include a step for transferring the manufactured display module to the supply unit LDU and transferring to the ion treatment unit ITU from the supply unit LDU. Then the display module may be ion-treated in the ion treatment unit ITU and moved to the moving unit TRU, or may be ion-treated in the ion treatment unit ITU, inspected for the quality in the inspection unit ISU, and then moved to the moving unit TRU. Further, the display module may be ion-treated in the ion treatment unit ITU, completely inspected for the quality in the inspection unit ISU, be re-transferred to the ion treatment unit ITU, and then moved to the moving unit TRU.

FIG. 1 schematically shows a block diagram of the display device manufacturing apparatus 10 in which a transfer apparatus of an embodiment to be described below is disposed or a portion of an apparatus in which the method of transferring a display module of an embodiment is performed. Accordingly, the display device manufacturing apparatus 10 is not limited to the shown type of block diagram, and may include components without limitation as long as components configured to perform the presented functions are included.

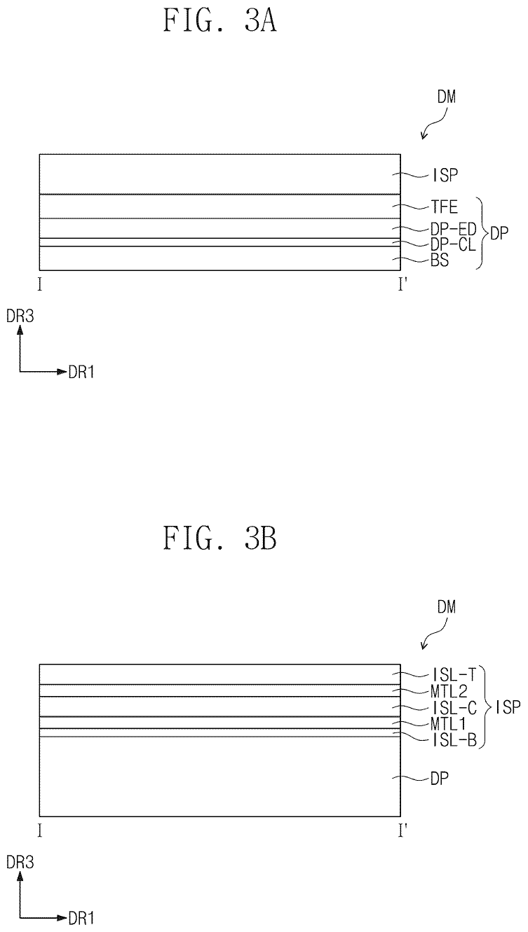

FIGS. 2, 3A, and 3B show a display module transferred using a transfer apparatus according to an embodiment. FIG. 2 is a perspective view of the display module according to an embodiment. FIGS. 3A and 3B are each a cross-sectional view corresponding to a line I-I′ of FIG. 2 according to embodiments.

An active area AA and a peripheral area NAA may be defined in the display module DM according to an embodiment. The active area AA may be activated according to an electrical signal. The peripheral area NAA may be disposed at least one side of the active area AA. In an embodiment, the peripheral area NAA may surround the active area AA.

An area in which pads PD and VID are disposed in the peripheral area NAA may be referred to as a pad area PDA. The pad area PDA may be a portion of the non-active area NAA. The pad area PDA may be disposed with a driving circuit or driving lines for driving the active area AA. The driving pads PD disposed in the pad area PDA may be electrically connected to the display panel DP or the input sensor ISP. The inspection pad VID may be for inspecting operation states, disconnection, or the like of driving wires, sensor electrodes, or the like. For the display module DM, the pads PD and VID may be exposed. Namely, the display module DM transferred using the transfer apparatus of an embodiment may be transferred with the pads PD and VID exposed outside. Through the pads PD and VID of the display module DM, the inspection unit ISU may inspect whether the display module DM operates normally.

The display module DM transferred using the transfer apparatus of an embodiment may be used in an electronic apparatus such as a monitor, a tablet, a notebook computer or the like. For example, the display module DM transferred using the transfer apparatus of an embodiment may be used in a middle or large-sized electronic apparatus and have a large-area display surface.

FIG. 2 and other drawings show a first directional axis DR1 to a third directional axis DR3, and the directions indicated by the first to third directional axes DR1, DR2, and DR3 described herein may be relative concepts and changed to other directions. In addition, the directions indicated by the first to third directional axes DR1, DR2, and DR3 may be described as the first to third directions DR1, DR2 and DR3, and refer to like reference numerals. The first directional axis DR1 and the second directional axis DR2 described herein may be orthogonal to each other, and the third directional axis DR3 may be a normal direction to a plane defined by the first and second directional axes DR1 and DR2.

The thickness direction of the display module DM may be parallel to the third directional axis DR3 that is a normal direction to a plane defined by the first directional axis DR1 and the second directional axis DR2. The display module DM may provide an image to a user through a display surface. In the specification, the front surface (or the top surface) and the rear surface (or the bottom surface) of each component are defined on the basis of a direction in which the image IM is displayed.

In the present specification, the expression “in a plan view” may mean a state of being viewed in the third direction DR3. In the present specification, the expression “in a cross-sectional view” may mean a state viewed in the first direction DR1 or the second direction DR2.

The display module DM may include a display panel DP and an input sensor ISP disposed on the display panel DP. The display panel DP and the input sensor ISP may be laminated in the third direction DR3.

FIG. 3A is a cross-sectional view showing the structure of the display panel DP in detail. The display panel DP according to an embodiment may include a base layer BS, a circuit layer DP-CL, a display element layer DP-ED, and an encapsulation layer TFE.

The base layer BS may be a member configured to provide a base surface with the circuit layer DP-CL disposed thereon. The base layer BS may be a rigid substrate, or a flexible substrate that is bendable, foldable, rollable, or the like. The base layer BS may be a glass substrate, a metal substrate, a polymer substrate or the like. However, the embodiment is not limited thereto, and the base layer BS may be an inorganic layer, an organic layer, or a composite material layer.

The circuit layer DP-CL may be disposed on the base layer BS. The circuit layer DP-CL may include an insulation layer, a semiconductor pattern, a conductive pattern, signal wires or the like. The insulation layer, the semiconductor layer, and the conductive layer may be provided on the base layer BS in a manner of coating, deposition or the like, and then, selectively patterned through a plurality of photolithography processes. Then, the semiconductor pattern, the conductive pattern, and the signal wires included in the circuit layer DP-CL may be provided. The circuit layer DP-CL may include a plurality of inorganic insulation layers and a plurality of organic insulation layers as the insulation layer.

The display element layer DP-ED may be disposed on the circuit layer DP-CL. The display element layer DP-ED may include light emitting elements. For example, the light emitting element layer DP-ED may include an organic light-emitting material, an inorganic light-emitting material, an organic-inorganic light-emitting material, quantum dots, quantum rods, micro LEDs, or nano LEDs. The light-emitting elements of the display element layer DP-ED may be electrically connected to driving elements of the circuit layer DP-CL and generate light in response to signals provided by the driving elements to display an image.

The encapsulation layer TFE may be disposed on the display element layer DP-ED. The encapsulation layer TFE may protect the light-emitting element layer DP-ED from a foreign matter such as moisture, oxygen and dust particles. The encapsulation layer TFE may encapsulate the light-emitting elements of the display element layer DP-ED. The encapsulation layer TFE may include at least one thin film for improving the optical efficiency of the display element layer DP-ED, or protecting the display element layer DP-ED.

The input sensor ISP may be disposed on the display panel DP. The input sensor ISP may sense an external input applied from the outside. The external input may include various types of external inputs including a part of the user's body, light, heat, a pen, pressure or the like. The input sensor may provide an input signal including information about the external input so that the display panel DP may sense the external input TC to generate the image IM corresponding to the external input. The input sensor ISP may be driven in various manners using static capacity, a resistive film, an infrared ray, a sound wave or a pressure, and the driving way is not limited to a certain one. In the embodiment, the input sensor ISP will be described to be driven in the static capacitive manner.

The input sensor ISP may be disposed on the display panel DP through successive processes. In this case, the input sensor ISP may be expressed as being directly disposed on the display panel DP. To be directly disposed may mean that a third element is not disposed between the input sensor ISP and the display panel DP. In other words, a separate adhesive member may not be disposed between the input sensor ISP and the display panel DP.

Referring to FIG. 3B, the input sensor ISP may include a sensor base layer ISL-B, sensor conductive layers MTL1 and MTL2, and sensor insulation layers ISL-C and ISL-T. The sensor base layer ISL-B may be directly disposed on the display panel DP.

The input sensor ISP may include the sensor base layer ISL-B. The sensor conductive layers MTL1 and MTL2 disposed on the sensor base layer ISL-B, and the sensor insulation layers ISL-C and ISL-T disposed on the sensor base layer ISL-B. For example, the input sensor ISP in an embodiment may include the sensor base layer ISL-B, the first sensor conductive layer MTL1, the first sensor insulation layer ISL-C, the second sensor conductive layer MTL2, and the second sensor insulation layer ISL-T that are sequentially laminated on the display panel DP in the third direction DR3.

The sensor base layer ISL-B may be an inorganic layer including at least any one among silicon nitride, silicon oxynitride, or silicon oxide. Alternatively, the sensor base layer ISL-B may be an organic layer including an epoxy resin, an acrylic resin, or an imide-based resin. The sensor base layer ISL-B may have a single layer structure, or a multilayer structure with layers laminated in the third direction DR3.

Each of the first sensor insulation layer ISL-C and the second sensor insulation layer ISL-T may include at least one of silicon nitride (SiN_{X}) and silicon oxynitride (SiO_{X}N_{Y}). In addition, the first insulation layer ISL2 and the second insulation layer ISL3 each may include silicon oxide (SiO_{X}). Meanwhile, the first sensor insulation layer ISL-C and the second sensor insulation layer ISL-T may include, as an inorganic layer, aluminum oxide, titanium oxide, zirconium oxide, and halfnium oxide. In the expressions of silicon nitride (SiN_{X}), silicon oxynitride (SiO_{X}N_{Y}), and silicon oxide (SiO_{X}), X and Y each are greater than 0.

The first sensor insulation layer ISL-C may be disposed on the first sensor conductive layer MTL1. The second sensor insulation layer ISL-T may be disposed on the second sensor conductive layer MTL2. The first sensor insulation layer ISL-C and the second sensor insulation layer ISL-T each may include an inorganic film. In addition, the first sensor insulation layer ISL-C and the second sensor insulation layer ISL-T each may include an organic film.

When the first sensor insulation layer ISL-C and the second sensor insulation layer ISL-T each include the organic film, the organic film may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a parylene-based resin.

Each of the first sensor conductive layer MTL1 and the second conductive layer MTL2 may have a single layer or a multilayer structure. The sensor conductive layer of the multilayer structure may have two or more layers of transparent conductive layers or metal layers. For example, the sensor conductive layer of the multilayer structure may have a structure in which transparent conductive layers and metal layers are laminated or metal layers including different metals are laminated.

The transparent conductive layer included in the first sensor conductive layer MTL1 and the second sensor conductive layer MTL2 may include indium tin oxide (ITO), indium zinc oxide (IZO), zinc oxide (ZnO), indium tin zinc oxide (ITZO), PEDOT, a metal nanowire, or graphene, etc. The metal layer included in the first sensor conductive layer MTL1 and the second sensor conductive layer MTL2 may include molybdenum, silver, copper, aluminum, or an alloy thereof.

Meanwhile, FIG. 3B illustrates the input sensor ISP including the laminated first sensor conductive layer MTL1 and second sensor conductive layer MTL2, but the embodiment is not limited thereto. For example, in an embodiment, the input sensor ISP may include one sensor conductive layer disposed on the sensor base layer ISL-B. In this case, one of the first sensor insulation layer ISL-C and the second sensor insulation layer ISL-T may be omitted.

In the first sensor conductive layer MTL1 and the second sensor conductive layer MTL2 or the like, when static electricity is generated by metal materials, discharge of the static electricity may occur. In this case, a portion of the sensor conductive layers MTL1 and MTL2 may be disconnected or a connection portion connecting the sensor conductive layers MTL1 and MTL2 to each other may be burnt.

Accordingly, when a metal material or an electrification material contacts or is rubbed with the top of the display module DM including the input sensor ISP, the display module DM is highly likely to be damaged. Accordingly, a transfer apparatus and transfer method for effectively eliminating the static electricity and not causing contact-electrification are required when the display module DM is transferred.

FIG. 4 is a perspective view of the transfer apparatus according to an embodiment. The transfer apparatus TMU of an embodiment may include the moving stage MST, the ionizer INZ, and the fixed moving unit FXM. The ionizer INZ may be disposed in one side of the moving stage MST. The fixed moving unit FXM may be positioned over the moving stage MST.

Meanwhile, the transfer apparatus TMU of an embodiment may further include a plurality of control units CUN-M, CUN-I, and CUN-P. The transfer apparatus TMU of an embodiment may include a stage control unit CUN-M configured to adjust movement and arrangement of the moving stage MST, an ionizer control unit CUN-I configured to control movement, arrangement, ion generation, and an ion supply amount, and a moving control unit CUN-P configured to control movement and arrangement of the fixed moving unit FXM and the degree of adsorption of the display module.

The transfer apparatus TMU of an embodiment may be disposed in the ion treatment unit ITU (see FIG. 1) in the display device manufacturing apparatus according to the embodiment shown in FIG. 1. In addition, the fixed moving unit FXM of the transfer apparatus TMU in an embodiment may be moved to other components adjacent to the ion treatment unit of the display device manufacturing apparatus, for example, the supply unit LDU, the inspection unit ISU, the moving unit TRU or the like.

The ionizer INZ in the transfer apparatus TMU of an embodiment may be positioned at a side of the display module DM mounted on the moving stage MST. The moving state MST may have the display module DM mounted thereon, and the ionizer INZ may be disposed in a pad area PDA side of the display module DM mounted on the moving stage MST.

The stage control unit CUN-M may be a portion configured to adjust the position of the moving stage MST. In addition, the stage control unit CUN-M may control the display module DM to be mounted thereon and fixed.

The ionizer INZ may provide ions to prevent an electrostatic discharge from occurring in the display module DM. The ionizer control unit CUN-I may control the movement and operation of the ionizer INZ. The ionizer INZ may further include operation control lines CL-M and CL-I other than the ionizer control unit CUN-I. The operation control line CL-M may be a portion through which signals for controlling the arrangement and movement of the ionizer INZ are provided, and an electrostatic elimination control line CL-I may be a portion through which signals for controlling the type and degree of electrostatic elimination of ions generated and emitted from the ionizer INZ.

The fixed moving unit FXM may fix to move the display module DM. The fixed moving unit FXM may fix to move the display module DM to the top of the moving stage MST, or pickup the display module from the moving stage MST to move the display module to another position. The moving control unit CUN-P may adjust the movement of the fixed moving unit FXM and fixing strength of the display module.

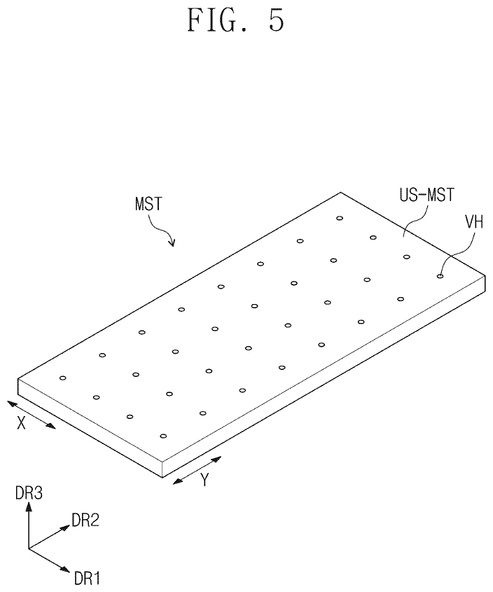

FIG. 5 is a perspective view of a moving stage according to an embodiment. Referring to FIGS. 4 and 5, the display module DM may be mounted on the moving stage MST. One side of the display module DM may be disposed to protrude from the moving stage MST to be adjacent to the ionizer INZ. For example, at least a portion of the pad area PDA of the display module may be disposed to protrude from the moving stage MST.

The top surface US-MST of the moving stage MST may be defined with a vacuum suction hole VH. The display module DM may be adsorbed and fixed by the vacuum suction hole VH to the moving stage MST.

The moving stage MST may be moved in an x-direction X or a y-direction Y. The X direction X may be parallel to the first direction DR1 and the Y direction Y may be parallel to the second direction DR2. However, the embodiment is not limited thereto, and the moving stage MST may be moved on a plane defined by the first direction DR1 and the second direction DR2.

A plurality of display modules DM may be mounted on the moving stage MST. The plurality of display modules DM may be arranged so that a pad area PDA side is adjacent to the ionizer INZ.

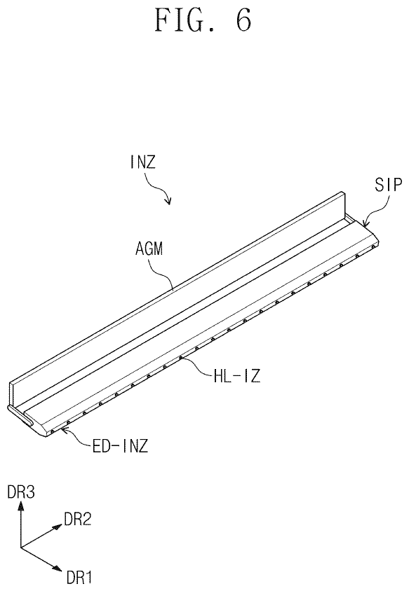

FIG. 6 is a perspective view of an ionizer according to an embodiment of the inventive concept. Referring to FIGS. 4 and 6, the ionizer INZ included in the transfer apparatus TMU of an embodiment may include an irradiation unit SIP configured to directly irradiate with ions, and an irradiation control unit AGM configured to fix and change the direction of the irradiation unit SIP. The irradiation unit SIP and irradiation control unit AGM of the ionizer INZ may be controlled and operated by the ionizer control unit CUN-I.

In an edge portion ED-INZ of the irradiation unit SIP, emission holes HL-INZ from which the ions are directly irradiated. The plurality of emission holes HL-IZ may be defined in the edge portion ED-INZ.

Plus (+) ions may be emitted from some of the emission holes HL-IZ, and minus (−) ions may be emitted from the other emission holes. The plus and minus ions may be concurrently irradiated or alternately irradiated at time intervals. Meanwhile, such an ion irradiation method is merely an example, and the operation type of the ionizer INZ is not limited to the above-described.

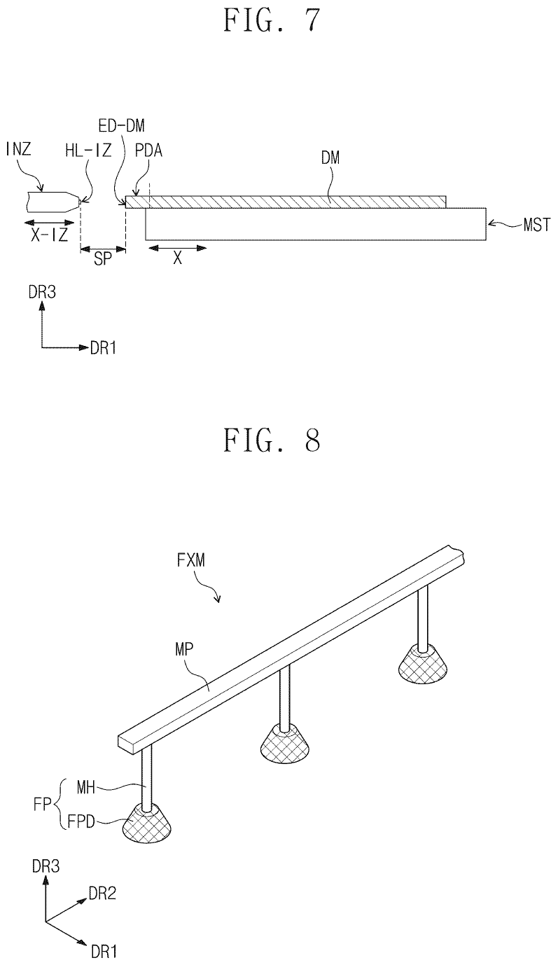

FIG. 7 shows an example positional relationship between the moving stage MST and the ionizer INZ. Referring to FIG. 7, the ionizer INZ may be positioned in one side of the moving stage MST with the display module DM mounted thereon. In the transfer apparatus of an embodiment, a first space SP between one side edge ED-DM of the display module DM and the ionizer INZ may be about 5 cm or longer. For example, in the transfer apparatus of an embodiment, the first space SP between one side edge ED-DM of the display module DM and the ionizer INZ may be about 10 cm or longer. Specifically, in the transfer apparatus of an embodiment, the first space SP between one side edge ED-DM of the display module DM and the ionizer INZ may be about 5 cm to about 50 cm.

In an embodiment, the first space SP may be a space between an edge of the pad area PDA and the ionizer INZ. In addition, in an embodiment, the first space SP may be a space between the emission holes HL-IZ of the ionizer INZ and one side edge ED-DM of the display module DM.

For the transfer apparatus of an embodiment in which the position of the ionizer INZ is adjusted for the first space SP to be at least about 5 cm, electrification of the sensor conductive layer of the input sensor caused by ion contact irradiation may be prevented.

When the space between the one side edge ED-DM of the display module DM and the ionizer is smaller than about 5 cm, a discharge may occur in the sensor conductive layer of the input sensor included in the display module DM according to an increase in the amount of the ions directly irradiated on the display module DM. In addition, when the space between the one side edge ED-DM of the display module DM and the ionizer is greater than about 50 cm, the electrostatic elimination properties using the ionizer INZ may be reduced.

Table 1 shows a failure rate of electrostatic discharge according to the space difference between the display module and the ionizer. The failure rate in Table 1 shows a failure rate due to a damage of the input sensor. In Comparative example 1, the display module is transferred using a transfer apparatus in which the space between the ionizer and the display module is smaller than about 5 cm, and in Example 1, the display module is transferred using a transfer apparatus of an embodiment in which the space between the ionizer and the display module is at least about 5 cm.

TABLE 1

| Division | Comparative example 1 | Example 1 |
|---|---|---|
| Failure rate (%) | 0.56 | 0.07 |

When comparing Comparative example 1 and Example 1, it may be understood that the failure rate of Example 1 exhibits about 88% reduction compared to Comparative example 1. In other words, for Example 1 using a transfer apparatus of an embodiment in which the space between the ionizer and the display module is at least about 5 cm, it may be understood that the electrostatic discharge is reduced and remarkably improve the failure rate of the input sensor.

FIG. 8 shows a fixed moving unit according to an embodiment. Referring to FIGS. 4 and 8, the fixed moving unit FXM in the transfer apparatus TMU in an embodiment may include pickup units FP and a transfer unit MP.

Each of the pickup units FP in the fixed moving unit FXM may include a vacuum suction unit MH and a pickup pad FPD. The vacuum suction unit MH may be defined with a suction hole HL. The suction hole HL may be a through-hole. The display module DM may be adsorbed to be fixed using a vacuum state via the suction hole HL. However, the vacuum suction unit MH may not directly contact the display module DM, and the suction hole HL may be spaced apart from the top surface of the display module DM.

The pickup pad FPD may surround at least a portion of the vacuum suction unit MH. The pickup pad FPD may be a portion directly contacting the display module DM.

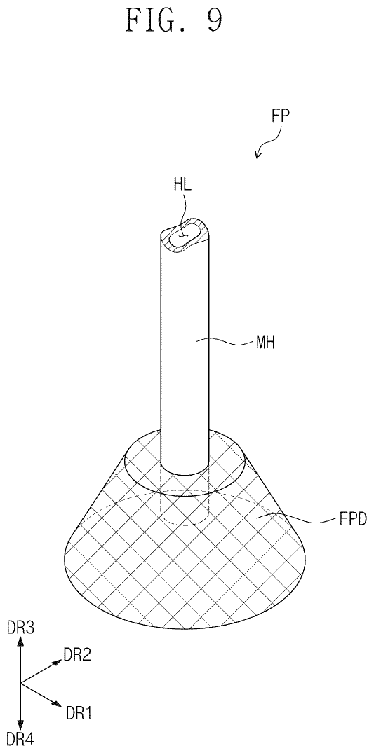

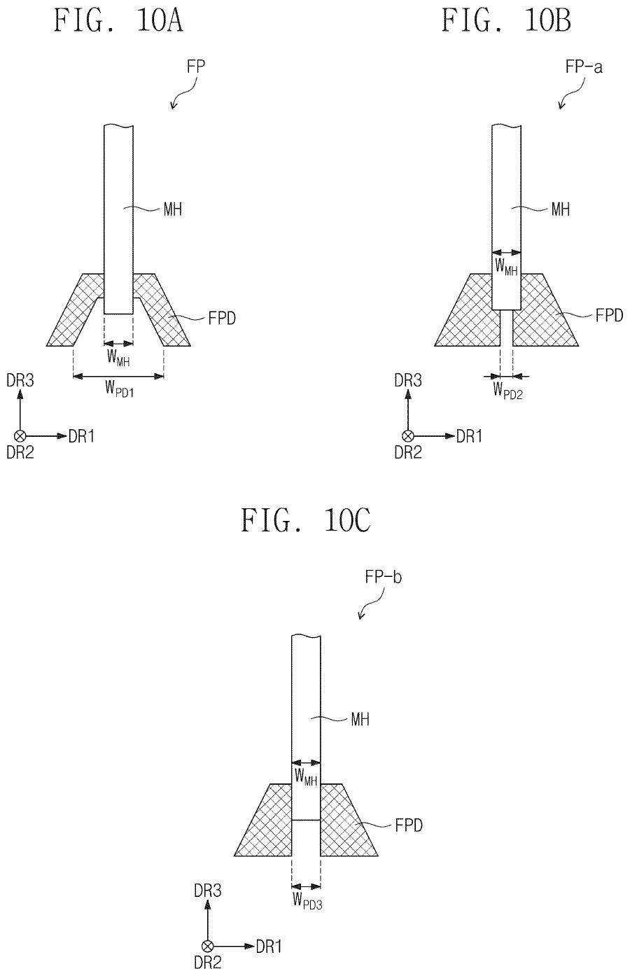

FIG. 9 is a perspective view of the pickup unit FP according to an embodiment of the inventive concept. FIGS. 10A to 10C each show a cross-section of the pickup unit FP according to an embodiment. Referring to FIGS. 9 and 10A to 10C, the pickup pad FPD may expose at least a portion of the suction hole HL and surround an edge portion of the vacuum suction unit MH.

Referring to FIG. 10A, the inner diameter W_{MH} of the vacuum suction unit MH with the suction hole HL defined therethrough in the pickup unit FP included in the fixed moving unit FXM of an embodiment may be smaller than the width WPD1 of an opening defined on the bottom of the pickup pad FPD so as to enable suction of the display module DM. However, the embodiment of the inventive concept is not limited thereto.

The inner diameter W_{MH} of the vacuum suction unit MH in the pickup unit FP-a according to the embodiment shown in FIG. 10B may be larger than the width WPD2 of an opening defined on the bottom of the pickup pad FPD so as to surround the vacuum suction unit MH and enable suction of the display module DM. In addition, the inner diameter W_{MH} of the vacuum suction unit MH in the pickup unit FP-b according to the embodiment shown in FIG. 10C may be substantially equal to the width WPD2 of an opening defined on the bottom of the pickup pad FPD so as to surround the vacuum suction unit MH and enable suction of the display module DM.

In FIGS. 9 and 10A to 10C, the pickup pad FPD is shown that the width of the pickup pad FPD becomes gradually wider from top to the bottom surface in a cross-sectional view. However, this is merely an example, and the shape of the pickup pad FPD is not limited thereto. The shape of the pickup pad FPD is not particularly limited as long as the vacuum suction unit MH may be permitted not to directly contact the display module but to fix and move the display module using the vacuum state provided through the vacuum suction unit MH.

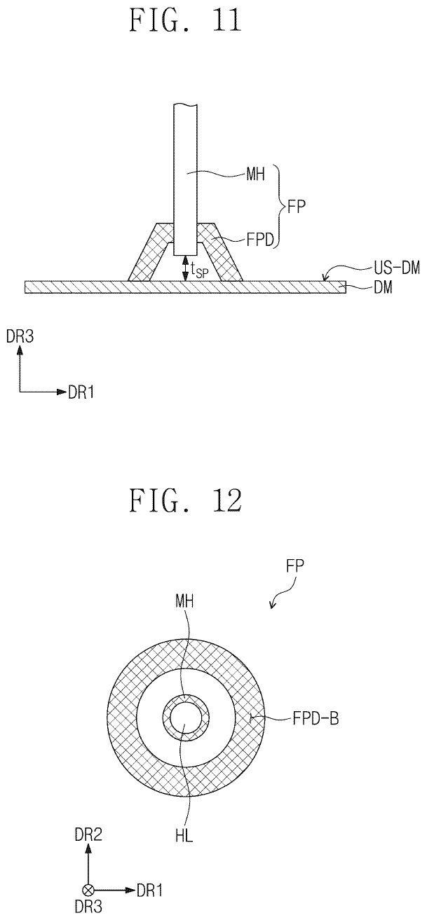

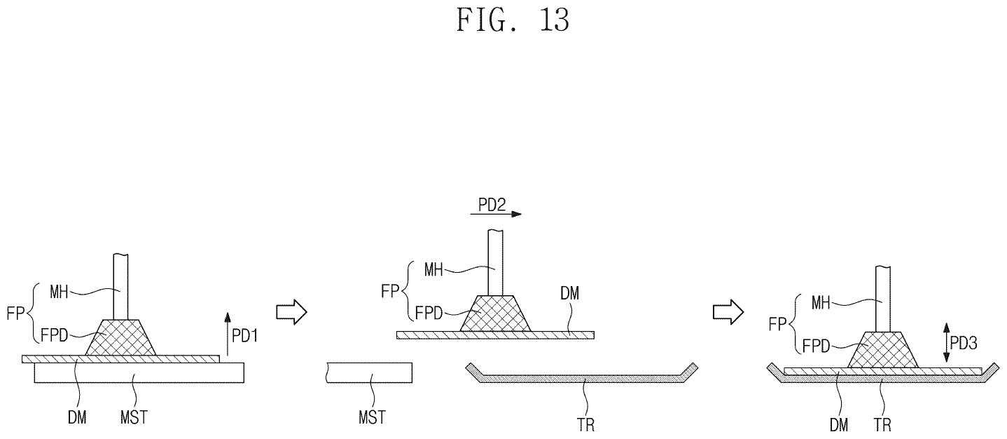

FIG. 11 shows an example state where a pickup unit is positioned on the display module. FIG. 12 shows an example bottom of a pickup unit. FIGS. 11 and 12 respectively show display module adsorption states using the pickup unit FP and a bottom surface shape of the pickup unit FP according to the embodiments described with reference to FIGS. 9 and 10A.

Referring to FIGS. 11 and 12, the vacuum suction unit MH in the transfer apparatus of an embodiment may be spaced apart from the top surface US-DM of the display module DM in a second space tsp. The second space tsp may be at least about 3 mm. The upper limit value of the second space tsp is not particularly limited, and the upper limit value of the second space tsp may be determined considering whether the display module DM may be stably fixed and moved through the vacuum suction unit MH. Namely, the upper limit value of the second space tsp may be determined according to the level of the vacuum-state provided through the vacuum suction unit MH of the pickup unit FP.

The vacuum suction unit MH may be provided with a metal material. Accordingly, when the vacuum suction unit MH and the display module become adjacent to each other by about 3 mm or smaller, the electrostatic discharge may occur in the display module DM due to the vacuum suction unit MH.

Table 2 below shows a range of a voltage at which the electrostatic discharge occurs according to the space between the vacuum suction unit MH and the display module DM.

TABLE 2

| Space (mm) | 1 | 3 | 5 |
|---|---|---|---|
| ESD voltage (V) | 400 | 1500 | 100000 |

Referring to Table 2, when the vacuum suction unit MH and the display module DM are spaced apart by at least about 3 mm and a voltage of at least about 1,500 V is induced, the electrostatic discharge may occur. Thus, when the vacuum suction unit MH and the display module DM are spaced apart by at least about 3 mm, the display module DM may be safely fixed and transferred using the pickup unit FP. When the pickup unit FP is moved toward the display module DM and fix the display module, the pickup pad FPD may be disposed to contact the top surface US-DM of the display module DM. The top surface US-DM of the display module DM, which contacts the pickup pad FPD, may be an input sensor ISP (see FIG. 2) side.

Referring to FIGS. 11 and 12, the pickup pad FPD may surround the vacuum suction unit MH in which the suction hole HL is defined. The bottom surface FPD-B of the pickup pad may contact the top surface of the display module DM. The pickup pad FPD may surround at least a portion of the vacuum suction unit MH so that the vacuum suction unit MH does not directly contact the display module DM, and the space between the vacuum suction unit MH and the display module DM may be maintained by the pickup pad FPD.

The pickup pad FPD may include a polymer material. The surface resistivity of the pickup pad FPD may be at least about 10¹² Ω/sq. When the pickup pad FPD of which the surface resistivity is at least about 10¹² Ω/sq is adsorbed onto the display module DM, the electrification due to contact of the pickup pad FPD may be reduced and the electrostatic discharge failure due to the contact of the pickup pad may be reduced.

Table 3 shows a failure rate of electrostatic discharge according to the difference in surface resistivity value of the pickup pad. The failure rate in Table 3 shows a failure rate due to the damage of the input sensor. Comparative example 2 is a failure rate of a display module transferred using a transfer apparatus including a pickup unit with the surface resistivity of about 10⁶ to about 10⁹ Ω/sq, and Example 2 is a failure rate of a display module transferred using a transfer apparatus of an embodiment in which the surface resistivity of the pickup pad is at least about 10¹² Ω/sq.

In Table 3, the failure rate comparison result is measured in a state where the space between the vacuum suction unit in the pickup unit and the display module is equally about 3 mm in both Comparative example 2 and Example 2.

TABLE 3

| Division | Comparative example 2 | Example 2 |
|---|---|---|
| Failure rate (%) | 9.92 | 4.24 |

When comparing Comparative example 2 and Example 2, it may be understood that the failure rate of Example 2 exhibits about 57% reduction compared to Comparative example 2. In other words, for Example 2 using a transfer apparatus of an embodiment in which the surface resistivity of the pickup pad is at least about 10¹² Ω/sq, it may be understood that the electrostatic discharge is reduced and remarkably improve the failure rate of the input sensor. Referring to FIG. 8 again, the fixed moving unit FXM in the transfer apparatus of the embodiment may include a plurality of pickup units FP. The plurality of pickup units FP may be fixed to the transfer unit MP to be concurrently moved. The plurality of display modules DM may be concurrently transferred using the plurality of pickup units FP.

FIG. 13 shows example steps of an operation method of a transfer apparatus of an embodiment. Referring to FIG. 13, the display module DM mounted on the moving stage MST may be moved from the moving stage MST using the pickup unit FP. The display module DM may be in a state where the static electricity has been eliminated using the ionizer and the operation failure has been inspected by the inspection unit ISU (see FIG. 1). Here, the moving direction PD1 of the fixed moving unit including the pickup unit FP may be a direction for spacing the display module DM from the moving stage MST.

Then, the display module DM fixed by the pickup unit FP may be transferred to the moving unit TRU (see FIG. 1) from the moving stage MST. FIG. 13 shows a transfer tray TR as an example moving unit. The moving direction PD2 of the fixed moving unit including the pickup unit FP may be a direction in which the display module DM is transferred toward the transfer tray TR.

The display module DM transferred toward the transfer tray TR may be put on the transfer tray TR and then the pickup unit FP may be desorbed from the display module DM. The moving direction PD3 of the fixed moving unit including the pickup unit FP on the transfer tray TR may be in the adjacent direction to or the spacing direction from the transfer tray TR.

The display module DM transferred to the transfer tray TR may be manufactured as a display device through additional display device manufacturing processes. For example, after being transferred to the transfer tray TR, various processes may be performed including a process of bonding optical members such as a polarization plate and the like to the display module DM, a process for adhering a driving circuit board or the like, a process for packing the display module with a housing, and the like.

The transfer apparatus of an embodiment may include the moving stage, the ionizer, and the fixed moving unit, and reduce a failure rate caused by static electricity by causing the space between the ionizer and the display module disposed on the moving stage to be at least about 5 cm and preventing the electrostatic discharge in the display module at the time of ion contact irradiation. In addition, the transfer apparatus of an embodiment may prevent the electrostatic discharge due to contact of the fixed moving unit by causing the space between the vacuum suction unit in the fixed moving unit and the display module to be at least about 3 mm and the surface resistivity of the pickup pad be at least about 10¹² Ω/sq, and may effectively transfer the display module using the fixed moving unit.

In addition, the transfer apparatus of an embodiment may reduce the electrostatic discharge failure of the display module during transfer of the display module including the input sensor. In particular for a display module with a middle or large display surface having a large area, a process for directly contacting the fixed moving unit to the top surface of the display module may be adopted, and in this case, even when the fixed moving unit is directly contacted, the electrostatic failure may be minimized when the transfer apparatus of the embodiment is used to transfer the display module.

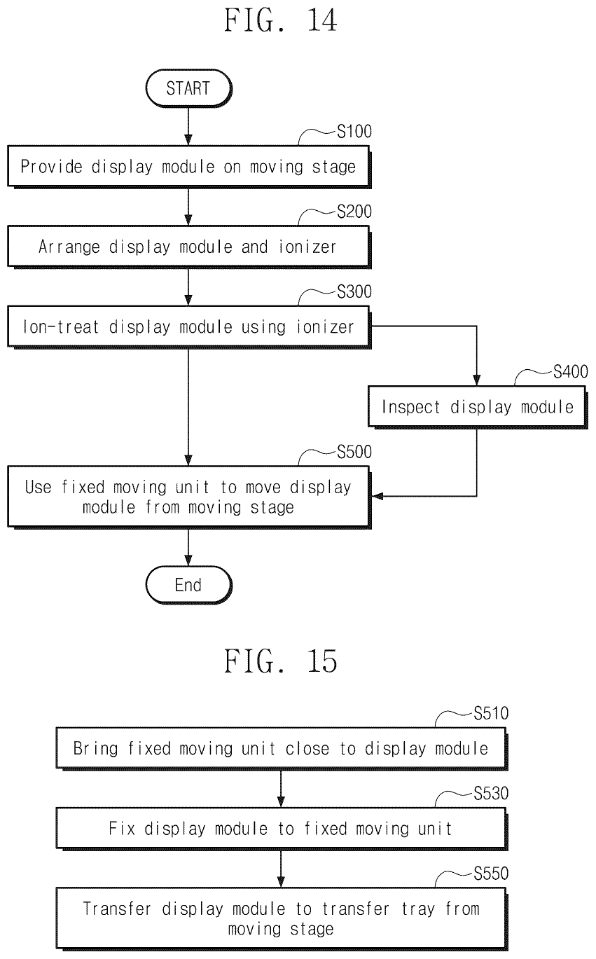

Hereinafter, referring to FIGS. 14 and 15, a method of transferring a display module of an embodiment will be described. In the description of the method of transferring a display module of an embodiment, the content overlapping with the above-described content referring to FIGS. 1 to 13 may not be repeated and be mainly focused on differences.

FIG. 14 is a flowchart showing a display module manufacturing method according to an embodiment. FIG. 15 is a detailed flowchart of a step for moving a display module from a moving stage among steps of a method of transferring a display module of an embodiment.

Referring to FIGS. 14 and 15, the method of transferring a display module of an embodiment may include a step S100 of providing a display module on a moving stage, a step S200 of arranging the display module and an ionizer, a step S300 of ion-treating the display module using the ionizer, and a step S500 of using a fixed moving unit to move the display module from the moving stage. In addition, the method of transferring a display module of an embodiment may further include a step S400 of inspecting the display module between a step S300 of ion-treating the display module and the step S500 of using a fixed moving unit to move the display module from the moving stage. The method of transferring a display module of an embodiment may be performed using the transfer apparatus of an embodiment.

The step S100 of providing a display module on a moving stage may be a step of using the transfer apparatus TMU (see FIG. 4) to transfer and fix the display module provided by the supply unit LDU (see FIG. 1) to the moving stage MST (see FIG. 4). In the step S100 of providing a display module on a moving stage, the display module may be adsorbed by the fixed moving unit FXM (see FIG. 4) to be transferred to the moving stage MST (see FIG. 4) from the supply unit LDU (see FIG. 1). In the step S100 of providing a display module on a moving stage, a plurality of display modules may be transferred onto the moving stage MST (see FIG. 4) at a time in the same step by means of the fixed moving unit FXM (see FIG. 4). However, the embodiment is not limited thereto, and the plurality of display modules DM may be individually transferred according to the relative positions of the supply unit LDU (see FIG. 1) and the moving stage MST (see FIG. 4), the sizes of the display modules DM, or the number of pickup units FP included in the fixed moving unit FXM (see FIG. 4).

In the step S100 of providing a display module on a moving stage, the display module may be provided on the moving stage so that the pad area PDA (see FIG. 4) of the display module faces toward the ionizer. In addition, the pad area in an embodiment may be positioned so that at least a portion of the pad area protrudes from the moving stage.

After the display module is provided on the moving stage, the space between the display module and the ionizer may be adjusted. Namely, after the step S100 of providing a display module on a moving stage, the step S200 of arranging the display module and an ionizer may be performed. In the step S200 of arranging the display module and an ionizer, at least one of the ionizer and the moving stage with the display module mounted thereon may be controlled to be moved so that the space between the display module and the ionizer is at least about 5 cm. The space between the display module and the ionizer may be the space between one side edge of the display module and the ionizer. For example, at least one of the moving stage and the ionizer may be controlled to be moved so that the space between an edge adjacent to the pad area of the display module and the emission holes of the ionizer is at least about 5 cm.

The step S300 of ion-treating the display module using the ionizer may be performed after the step of arranging the display module and the ionizer so as to cause the space between the display module and the ionizer to be at least about 5 cm. Electrification of the surface or the periphery of the display module may be controlled by irradiating the display module with the ions through the emission holes HL-IZ (see FIG. 6) of the ionizer.

After the step of ion-treating the display module using the ionizer, the step S500 of moving the ion-treated display module to the moving stage using the fixed moving unit may be performed. Namely, the display module electrified using the ionizer may be transferred to the moving unit TRU (see FIG. 1). Meanwhile, the step S400 of inspecting the display module may be performed between the step S300 of ion-treating the display module and the step S500 of using a fixed moving unit to move the display module from the moving stage.

The display module electrified in the step S300 of ion-treating the display module using an ionizer may be moved to the inspection unit ISU (see FIG. 1) using the transfer apparatus. The display module moved to the inspection unit ISU (see FIG. 1) may be inspected to determine the normal operation, the appearance quality or the like, and then transferred to the moving unit TRU (see FIG. 1) using the transfer apparatus. In addition, the display module may be inspected to determine failure or not and then transferred to the moving unit TRU (see FIG. 1) via the ion treatment unit ITU (see FIG. 1) using the transfer apparatus.

The step S500 of moving the display module to the moving stage may include a step S510 of bringing the fixed moving unit close to the display module, a step S530 of fixing the display module to the fixed moving unit, and a step S550 of transferring the display module to a transfer tray from the moving stage.

The step S510 of bringing the fixed moving unit close to the display module may be a step of bringing the fixed moving unit close to the display module so that a pickup pad of the fixed moving unit contacts the top surface of the display module.

The step S530 of fixing the display module to the fixed moving unit may be a step of fixing the display module using a vacuum state provided through a vacuum suction unit after contacting the pickup pad of the fixed moving unit to the top surface of the display module through the step of brining the fixed moving unit close to the display module.

The step S550 of transferring the display module to a transfer tray from the moving stage may be a step of fixing the display module to the fixed moving unit and then moving the fixed moving unit to transfer the display module to the transfer tray. The transfer tray TR (see FIG. 13) may be a component on which the ion-treated display module is moved and put, and be one type of the moving unit TRU.

When the display module is fixed to be moved using the transfer apparatus in each of the steps of the method of transferring a display module of an embodiment, the fixed moving unit may include a vacuum suction unit and a pickup pad. In the step S100 of providing a display module on a moving stage and the step S500 of using a fixed moving unit to move the display module from the moving stage, the display module may be fixed to the fixed moving unit in the transfer apparatus of an embodiment and then moved. In addition, in the step S530 of fixing the display module to the fixed moving unit and a step S550 of transferring the display module to a transfer tray from the moving stage, the display module may be transferred with the pickup pad of the fixed moving unit fixed to the display module.

When the display module is adsorbed onto the fixed moving unit and then fixed and moved, the fixed moving unit may be spaced to have the space of at least about 3 mm from the top surface of the display module. In addition, the surface resistivity of the pickup pad directly contacting the display module may be at least about 10¹² Ω/sq.

In addition, before and after the step S400 of inspecting the display module among the steps of the method of transferring a display module of an embodiment, the position of the display module may be changed after the display module is adsorbed onto the fixed moving unit. Even in this case, the fixed moving unit is spaced apart by at least about 3 mm from the top surface of the display module, and the surface resistivity of the pickup pad directly contacting the display module may be at least about 10¹² Ω/sq.

The method of transferring a display module of an embodiment may be performed using the transfer apparatus of an embodiment including the moving stage, the ionizer, and the fixed moving unit. The method of transferring a display module of an embodiment may minimize the electrostatic discharge failure during transfer of the display module by including a step of arranging the display module and the ionizer so as to causing the space between the display module and the ionizer to be at least about 5 cm, a step of ion-treating the display module using the ionizer, and a step of moving the display module using the fixed moving unit in a state where the fixed moving unit includes the vacuum suction unit and the pickup pad and the vacuum suction unit and the display module are spaced apart by at least about 3 mm. In addition, even in a state where the pickup pad contacts the display module, contact electrification may be prevented to reduce the electrostatic discharge failure by causing the surface resistivity of the pickup pad to be at least about 10¹² Ω/sq.

The transfer apparatus according to an embodiment may include the ionizer arranged by a prescribed space or greater with the display module to improve electrostatic discharge failure caused by ion contact irradiation.

The transfer apparatus according to an embodiment may decrease electrostatic discharge generated at the time of contacting the display module including the input sensor to reduce damages to the input sensor.

The method of transferring a display module according to an embodiment may include a step of performing arrangement and ion treatment by means of the ionizer to minimize damages to the display module due to electrostatic discharge.

While the inventive concept has been described with reference to embodiments thereof, it will be clear to those of ordinary skill in the art to which the invention pertains that various changes and modifications may be made to the embodiments without departing from the spirit and technical area as defined in the appended claims and their equivalents.

Thus, the scope of the inventive concept shall not be restricted or limited by the foregoing description, but be determined by the broadest permissible interpretation of the following claims.

What is claimed is:

1. A transfer apparatus comprising:
a moving stage configured to mount a display module;
an ionizer positioned at a side of the moving stage and configured to be spaced apart by a first space of about 5 cm or more from a side edge of the display module; and
a fixed moving unit disposed over the moving stage and configured to adsorb and to move the display module.

2. The transfer apparatus of claim 1, wherein the fixed moving unit comprises:
a vacuum suction unit having suction holes; and
a pickup pad surrounding at least a portion of the vacuum suction unit and configured to contact the display module.

3. The transfer apparatus of claim 2, wherein
the vacuum suction unit is provided with a metal material, and
the vacuum suction unit is configured to be spaced apart from the display module by a second space of about 3 mm or more.

4. The transfer apparatus of claim 2, wherein a surface resistivity of the pickup pad is about 10¹² Ω/sq or more.

5. The transfer apparatus of claim 1, wherein the first space is about 10 cm or more.

6. The transfer apparatus of claim 1, wherein
the display module comprises an active area and a pad area disposed in at least one side of the active area and having a plurality of pads disposed therein, and
the first space is between an edge of the pad area and the ionizer.

7. The transfer apparatus of claim 6, wherein the moving stage is configured to mount the display module with at least a portion of the pad area protruding from one side of the moving stage.

8. The transfer apparatus of claim 1, wherein
the display module comprises a display panel and an input sensor disposed on the display panel and comprising a sensor conductive layer, and
the fixed moving unit is configured to be adsorbed to an input sensor side of the display panel.

9. The transfer apparatus of claim 1, wherein
the moving stage is configured to mount a plurality of display modules, and the plurality of display modules are arranged to be parallel to a side of the ionizer.

10. A transfer apparatus comprising:
a moving stage configured to mount a display module;
an ionizer spaced apart from a side of the moving stage; and
a fixed moving unit disposed over the moving stage and configured to adsorb and to move the display module,
wherein the fixed moving unit comprises a vacuum suction unit having a suction hole, and a pickup pad surrounding at least a portion of the vacuum suction unit and contacting the display module, and
wherein the ionizer is configured to be spaced apart from a side edge of the display module by a first space of about 5 cm or more, and the vacuum suction unit is configured to be spaced apart from a top surface of the display module by a second space of about 3 mm or more.

11. The transfer apparatus of claim 10, wherein the vacuum suction unit is provided with a metal material and the pickup pad is provided with a polymer material.

12. The transfer apparatus of claim 11, wherein a surface resistivity of the pickup pad is about 10¹² Ω/sq or more.

13. The transfer apparatus of claim 10, wherein
the display module comprises an active area and a pad area disposed in at least one side of the active area and having a plurality of pads disposed therein, and
the first space is between an edge of the pad area and the ionizer.

14. The transfer apparatus of claim 10, wherein
the display module comprises a display panel and an input sensor disposed on the display panel and comprising a sensor conductive layer, and
the fixed moving unit is configured to adsorb an input sensor side of the display panel.

15. A method of transferring a display module comprising:
providing a display module on a moving stage;
arranging the display module and an ionizer to be spaced apart by a space of about 5 cm or more;
ion-treating the display module using the ionizer to form an ion-treated display module; and
using the fixed moving unit to move the ion-treated display module from the moving stage.

16. The method of claim 15,
wherein the fixed moving unit comprises a vacuum suction unit having a suction hole defined therethrough, and a pickup pad surrounding at least a portion of the vacuum suction unit, and
wherein the moving the display module from the moving stage comprises:
bringing the fixed moving unit close to the display module so that the pickup pad contacts a top surface of the display module;
fixing the display module to the fixed moving unit; and
moving the fixed moving unit to transfer the display module to a transfer tray from the moving stage.

17. The method of claim 15, further comprising:
inspecting the display module between the ion-treating the display module and the using the fixed moving unit to move the display module from the moving stage.

18. The method of claim 15, wherein
the fixed moving unit comprises a vacuum suction unit having a suction hole, and a pickup pad surrounding at least a portion of the vacuum suction unit and contacting the display module, and
the vacuum suction unit and the display module are spaced apart by a second space of about 3 mm or more.

19. The method of claim 18, wherein a surface resistivity of the pickup pad is about 10¹² Ω/sq or more.

20. The method of claim 15, wherein
the display module comprises a display panel and an input sensor disposed on the display panel and comprising a sensor conductive layer, and
the fixed moving unit is adsorbed to an input sensor side of the display panel.
